(19) United States
(12) Patent Application Publication
(10) Pub. No.: US 2002/0111011 A1
(43) Pub. Date: Aug. 15, 2002

(54) Method for forming a contact plug without a dimple surface

(76) Inventors: King-Lung Wu, Tainan (TW); Horng-Nan Chern, Chia-Li Chen (TW)

Correspondence Address: Powell, Goldstein, Frazer & Murphy, LLP, Suite 600, 1001 Pennsylvanic Avenue, Washington, DC, 20004, US

(21) Appl. No.: 09/783,854

(22) Filed: Feb. 15, 2001

(51) Int. Cl. H01L 21/4763; H01L 21/44

(52) U.S. Cl. 438/618; 438/640; 438/684

(57) ABSTRACT

A method for forming a contact plug without a dimple surface is provided. The present method is characterized in that forming a trench-shaped opening penetrating a dielectric layer formed on a semiconductor substructure having a lower electrical conductor, and forming a liner layer with a tapered width decreasing from the top of the trench-shaped opening to the bottom thereof, and then forming a conductive plug to fill the trench-shaped opening. Since the width of the liner layer is decreased gradually from the top of the trench-shaped opening, a seam is formed in the trench-shaped opening below the surface of the dielectric layer when depositing a conductive layer over the dielectric layer and the trench-shaped opening for the conductive plug. Thereby, a conductive plug without a dimple surface is formed in the trench-shaped opening by etching back the conductive layer.

### BACKGROUND OF THE INVENTION

1. Field of the Invention

The present invention relates to a method for forming a contact plug, and more particularly to a method for forming a contact plug without a dimple surface in a semiconductor device.

2. Description of the Prior Art

Modern semiconductor devices are built on a silicon substrate that has P+ and N+ type doped regions in the substrate as basic elements of the device that must be connected in a specific configuration to form a desired circuit. The circuit must then be accessible to the outside world through conducting pads for testing and through bonding into a packaged chip. To form a semiconductor circuit, at least one layer of a conducting material such as metal or heavily-doped polysilicon must be deposited and patterned to form contacts and interconnects between the different regions of the chip. Polysilicon, when used as contact plugs, need to be doped N type when contacting N-regions and P type for contacting P-regions in order to avoid inter-diffusion and dopant compensation. A polysilicon film can be doped during deposition, i.e., in-situ doping, by adding arsine, phosphine or diborane to a gas mixture when a film is deposited at low pressure in a pyrolitic decomposition process of silane at approximately 600° C. Polysilicon film can also be doped after deposition by an ion implantation process or by a diffusion process.

When polysilicon is used in contact plug, it is usually formed in a dielectric layer, which separates a multiplicity of plugs, interconnects and circuits. In order to form a contact plug, a contact window or opening must be first formed in the dielectric layer by selective etching to expose portions of the underlying circuit or a lower interconnect layer. After polysilicon is deposited into the contact window, it connects the lower interconnect layer to an upper interconnect layer that is subsequently deposited on the top of the interlayer dielectric material.

While, as shown in FIG. 1A, when depositing a polysilicon layer 102 on a dielectric layer 101 over a semiconductor substructure 100 having a lower conductor and an opening 103 formed in the dielectric layer 101, a seam 104 is formed in the opening 103 and even exceeds the surface of the dielectric layer 101. Referring to FIG. 1B, when etching back the polysilicon layer 102 to form a polysilicon plug 103 in the opening 103, the seam 104 is easily opened, and then forming a dimple on the surface of the polysilicon plug 103.

The dimple surface of the polysilicon plug 103 induces the following problems:

1. When an interpoly dielectric layer, such as an oxide layer, is deposited on the polysilicon plug 103 for a node contact thereof, the planarization of the interpoly dielectric layer is bad, and thus the bad planarization induces a bad photo window of the interpoly dielectric layer.

2. The oxide residue is fully filled this dimple after the oxide layer served as the interpoly dielectric layer is anisotropically etched to form a node contact opening for the polysilicon plug 103, and thus the oxide residue will induce the node contact open.

Accordingly, it is desirable to provide a method for forming a contact plug without a dimple surface, which can alleviate the above drawbacks of the conventional method.

### SUMMARY OF THE INVENTION

It is one object of the present invention to provide a method for forming a contact plug without a dimple surface, in which a liner layer with a tapered width is formed along each sidewall of a trench-shaped opening penetrating a dielectric layer formed on a semiconductor substructure having a lower electrical conductor. The width of the liner layer decreases gradually from the top of the trench-shaped opening, and thus a seam could be formed in the trench-shaped opening below the dielectric layer when depositing a conductive layer over the dielectric layer and the trench-shaped opening for forming the conductive plug. Thereby, a conductive plug without a dimple surface could be obtained by etching back the conductive layer.

It is another object of the present invention to provide a method for forming a contact plug without a dimple surface, so that the planarization of an interlayer dielectric layer for forming a node contact of the conductive plug is improved and the photo window of the interlayer dielectric layer is also improved.

In order to achieve the above objects, the present invention provides a method for forming a contact plug without a dimple surface, which comprises providing a first conductor layer, and forming a first dielectric layer on the first conductor layer. Subsequently, removing a part of the first dielectric layer until exposing the surface of the first conductor layer, thereby forming a trench in the first dielectric layer. Then, forming a second dielectric layer on the first dielectric layer and the surface of the trench, wherein the second dielectric layer has a width tapered from the top of the trench to the bottom thereof. Thereafter, etching back the second dielectric layer to form a liner layer on each sidewall of the trench. Finally, forming a second conductor layer in the trench.

### BRIEF DESCRIPTION OF THE DRAWINGS

The foregoing and other advantages and features of the invention will be apparent from the following more particular description of preferred embodiments of the invention, as illustrated in the accompanying drawings.

FIG. 1A to FIG. 1B depict cross-sectional views of various steps for forming a polysilicon plug in the prior art, in which a dimple is formed on the surface of the polysilicon plug; and

FIG. 2A to FIG. 2D depict cross-sectional views of various steps for forming a conductive plug in a trench-shaped opening according to the present invention.

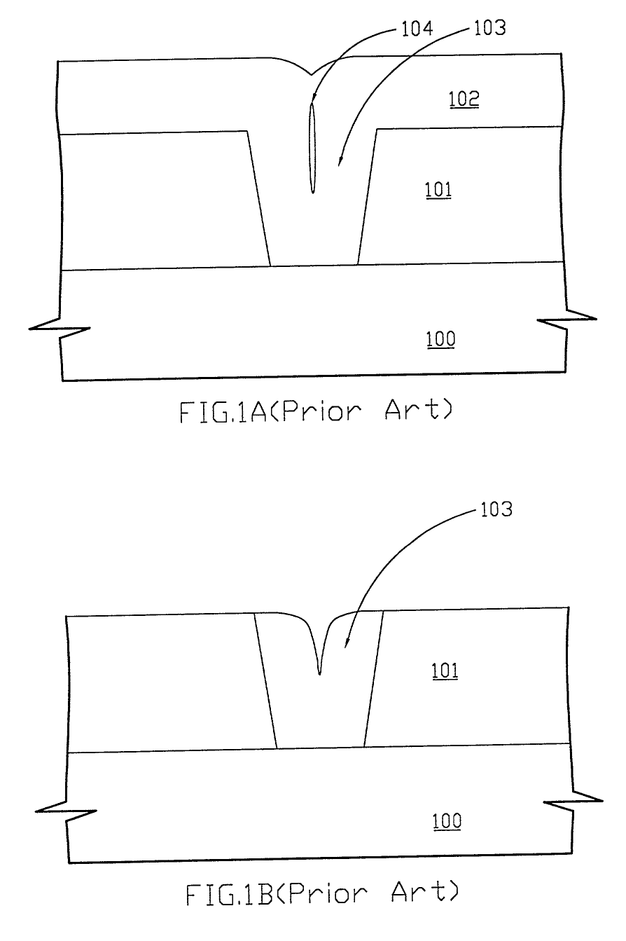

### DESCRIPTION OF THE PREFERRED EMBODIMENTS

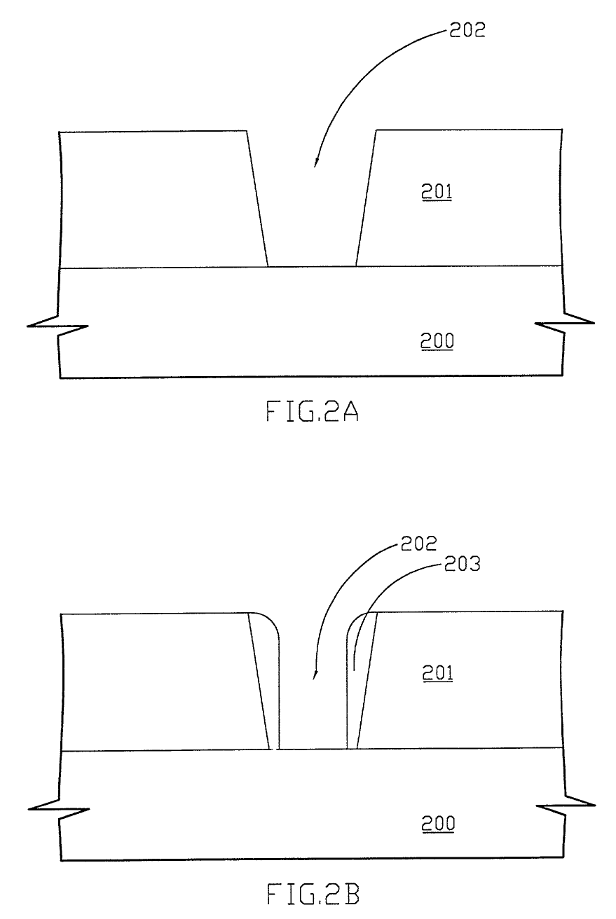

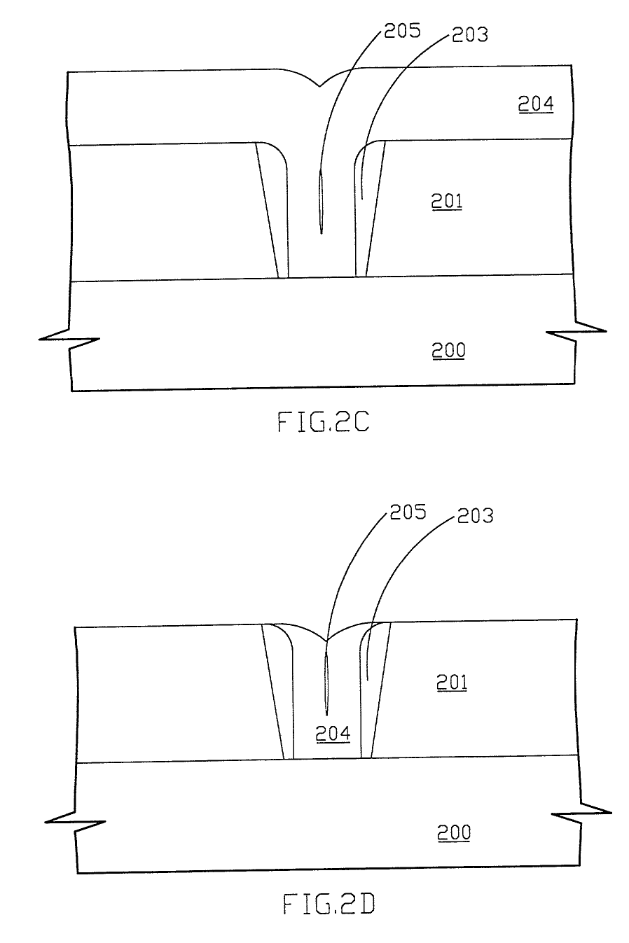

Referring to FIG. 2A, firstly, forming a first dielectric layer 201 on a semiconductor substructure 200 having a lower conductor. Next, forming a patterned resist film on the first dielectric layer 201, and then anisotropically etching the first dielectric layer 201 using the patterned resist film as a mask to thereby transfer the pattern of the resist film to the first dielectric layer 201, forming a trench-shaped opening 202 to penetrate the first dielectric layer 201.

The first dielectric layer 201 can be formed of BPSG (borophospho-silicate glass) by way of an atmospheric pressure chemical vapor deposition method utilizing reaction gases of TEOS/O3, TEB (tri-ethyl-borate) and TMPO (tri-methyl-phosphate). The first dielectric layer 201 of BPSG also can be formed by a plasma enhanced chemical vapor deposition method utilizing reaction gases of TEOS, O3/O2, TMP and TMB at the temperature of about 400˜500° C. and the operation pressure of about 10 torr.

Alternately, the first dielectric layer 201 is formed of silicon dioxide by way of an atmospheric pressure chemical vapor depostion method utilizing SiH₄ as the reaction gas at the temperature of about 400˜500° C. and the operation pressure of about 10 torr. The first dielectric layer 201 of silicon dioxide also can be formed of a low pressure chemical vapor depostion method utilizing TEOS/O₃ as the reaction gas at the temperature of about 650˜850° C. and the operation pressure of about 0.1˜5 torr. And, the first dielectric layer 201 of silicon dioxide can be formed by a plasma enhanced chemical vapor depostion method utilizing SiH₄ as the reaction gas at the temperature of about 300˜400° C. and the operation pressure of about 1˜10 torr.

Moreover, the first dielectric layer 201 can be anisotropically etched by way of a reactive ion etching method utilizing a source gas selected from the group consisting of CF₄, CHF₃, C₂F₆ and C₃F₈, to form the trench-shaped opening 202.

Next, referring to FIG. 2B, forming a second dielectric layer on the first dielectric layer 201 and the trench-shaped opening 202. The factors, such as gas flow rate, gas ratio, operation pressure and RF power, influencing the properties of the second dielectric layer, are varied so as to the second dielectric layer has a bad step coverage on the two sidewalls of the trench-shaped opening 202. As a result, the second dielectric layer has a width tapered from the top of the trench-shaped opening 202 to the bottom thereof. And then, etching back the second dielectric layer to form a liner layer 203 of the second dielectric along each sidewall of the trench-shaped opening 202. The width of the liner layer 203 is decreased from the top of the trench-shaped opening 202 to the bottom thereof. The second dielectric layer can be formed of silicon nitride by way of a plasma enhanced chemical vapor deposition method, using SiH₂Cl₂ and NH₃ as reaction gases, with a flow rate about 100˜140 sccm for SiH₂Cl₂ and about 320˜400 sccm for NH₃, under the temperature about 750° C. and the operation pressure about 40 Pa.

Besides, the second dielectric layer can be formed of silicon dioxide by way of a plasma enhanced chemical vapor deposition method. The conditions for forming this silicon dioxide layer as follows: the power is about 440˜500 W to about 150˜200 W for high frequency power to low frequency power, the reaction gases are TEOS/O₂ with a gas ratio of about 1:10 to about 1:12, and having a flow rate about 80˜120 sccm for TEOS, about 800˜1200 sccm for O₂′ under the temperature of about 400° C. and the operation pressure about 3.5 torr to 4.0 torr, to obtain a bad step coverage on the trench-shaped opening 202.

In this embodiment, a liner layer 203 with a tapered width decreasing from the top of the trench-shaped opening 202, along each sidewall of the trench-shaped opening 202, is formed. And thus, forming the inner top width of the trench-shaped opening 202 about 400˜500 angstroms and the inner bottom width thereof about 100 angstroms.

The second dielectric layer can be etched back by way of a reactive ion etching method so as to form the liner layer 203. When the second dielectric layer is formed of silicon nitride, NF₃ can be used as the etchant gas. While a source gas selected from the group consisting of CF₄, CHF₃, C₂F₆ and C₃F₈ can be used as the etchant gas for the second dielectric layer of silicon dioxide.

Referring to FIG. 2C, subsequently, forming a conductive layer 204, such as a polysilicon layer, over the first dielectric layer 201 and the trench-shaped opening 202. The polysilicon layer can be formed by way of a low pressure chemical vapor deposition method utilizing a reaction gas of SiH₄ at the temperature of about 600˜650° C. and the operation pressure of about 0.3˜0.6 torr. Since the width of the liner layer 203 is decreased gradually from the top of the trench-shaped opening 202 to the bottom thereof, a seam 205 is formed in the trench-shaped opening 202 and below the surface of the first dielectric layer 201.

Referring to FIG. 2D, at final, etching back the conductive layer 204 to form a conductive plug 204 in the trench-shaped opening 202. When the conductive layer 204 is formed of polysilicon, the polysilicon layer can be etched back by way of a reactive ion etching method utilizing a source gas selected from the group consisting of Cl₂, HCl and SiCl₄. Since the seam 205 is formed below the surface of the first dielectric layer 201, it is not opened when etching back the conductive layer 204. Therefore, there is no dimple formed on the surface of conductive plug 204. The planarization of the interlayer dielectric layer formed over the conductive plug 204 for a node contact is improved and the photo window of the interlayer dielectric layer is also improved.

The preferred embodiment is only used to illustrate the present invention, not intended to limit the scope thereof. Many modifications of the preferred embodiment can be made without departing from the spirit of the present invention.

What is claimed is:

1. A method for forming a contact plug without a dimple surface, comprising:
providing a first conductor layer;
forming a first dielectric layer on said first conductor layer;
removing a part of said first dielectric layer until exposing the surface of said first conductor layer, thereby forming a trench in said first dielectric layer;
forming a second dielectric layer on said first dielectric layer and the surface of said trench, wherein said second dielectric layer has a width tapered from the top of said trench to the bottom thereof;
etching back said second dielectric layer until exposing said first conductor layer to form a liner layer on each sidewall of said trench; and
forming a second conductor layer in said trench.

2. The method of claim 1, wherein said first dielectric layer is formed of BPSG (borophospho-silicate glass).

3. The method of claim 2, wherein said first dielectric layer of BPSG is formed of an atmospheric pressure chemical vapor deposition method utilizing reaction gases of TEOS/O3, TEB (tri-ethyl-borate) and TMPO (tri-methyl-phosphate).

4. The method of claim 2, wherein said first dielectric layer of BPSG is formed of a plasma enhanced chemical vapor deposition method utilizing reaction gases of TEOS, O₃/O₂, TMP and TMB at the temperature of about 400˜500° C. and the operation pressure of about 10 torr.

5. The method of claim 1, wherein said first dielectric layer is formed of silicon dioxide.

6. The method of claim 5, wherein said first dielectric layer of silicon dioxide is formed of an atmospheric pressure chemical vapor depostion method utilizing SiH₄ as the reaction gas at the temperature of about 400˜500° C. and the operation pressure of about 10 torr.

7. The method of claim 5, wherein said first dielectric layer of silicon dioxide is formed of a low pressure chemical vapor depostion method utilizing TEOS/O₃ as the reaction gas at the temperature of about 650˜850° C. and the operation pressure of about 0.1˜5 torr.

8. The method of claim 5, wherein said first dielectric layer of silicon dioxide is formed of a plasma enhanced chemical vapor depostion method utilizing SiH₄ as the reaction gas at the temperature of about 300˜400° C. and the operation pressure of about 1˜10 torr.

9. The method of claim 2, wherein said first dielectric layer is partly removed by way of anisotropically etching through a reactive ion etching method utilizing a source gas selected from the group consisting of CF₄, CHF₃, C₂F₆ and C₃F₈.

10. The method of claim 5, wherein said first dielectric layer is partly removed by way of anisotropically etching through a reactive ion etching method utilizing a source gas selected from the group consisting of CF₄, CHF₃, C₂F₆ and C₃F₈.

11. The method of claim 1, wherein said second dielectric layer is formed of silicon nitride.

12. The method of claim 11, wherein said second dielectric layer of silicon nitride is formed by way of plasma enhanced chemical vapor deposition method, using reaction gases of SiH₂Cl₂ with a flow rate about 100˜140 sccm and NH₃ with a flow rate about 320˜400 sccm, under the temperature of about 750° C. and the operation pressure about 40 Pa.

13. The method of claim 11, wherein said second dielectric layer of silicon nitride is etched back by a reactive ion etching method utilizing NF₃ as an etchant gas to form a liner layer of silicon nitride along each sidewall of said trench, said liner layer having a width tapered from the top of said trench to the bottom thereof.

14. The method of claim 12, wherein said second dielectric layer of silicon nitride is etched back by a reactive ion etching method utilizing NF₃ as an etchant gas to form a liner layer of silicon nitride along each sidewall of said trench, said liner layer having a width tapered from the top of said trench to the bottom thereof.

15. The method of claim 1, wherein said second dielectric layer is formed of silicon dioxide.

16. The method of claim 15, wherein said silicon dioxide layer is formed by way of plasma enhanced chemical vapor deposition method, utilizing reaction gases of TEOS/O₂ with a gas ratio about 1:10 to about 1:12, and a flow rate about 80˜120 sccm for TEOS and about 800˜1200 sccm for O2, at the temperature about 400° C. and the operation pressure about 3.5˜4.0 torr under the high frequency power about 440˜500 W.

17. The method of claim 15, wherein said silicon dioxide layer is formed by way of plasma enhanced chemical vapor deposition method, utilizing reaction gases of TEOS/O₂ with a gas ratio about 1:10 to about 1:12, and a flow rate about 80˜120 sccm for TEOS and about 800˜1200 sccm for O2, at the temperature about 400° C. and the operation pressure about 3.5˜4.0 torr under the low frequency power about 440˜500 W.

18. The method of claim 15, wherein said silicon dioxide layer is etched back by a reactive ion etching method utilizing a source gas selected from the group consisting of CF₄, CHF₃, C₂F₆ and C₃F₈ to form a liner layer of silicon dioxide along each sidewall of said trench, said liner layer having a width tapered from the top of said trench to the bottom thereof.

19. The method of claim 16, wherein said silicon dioxide layer is etched back by a reactive ion etching method utilizing a source gas selected from the group consisting of CF₄, CHF₃, C₂F₆ and C₃F₈ to form a liner layer of silicon dioxide along each sidewall of said trench, said liner layer having a width tapered from the top of said trench to the bottom thereof.

20. The method of claim 17, wherein said silicon dioxide layer is etched back by a reactive ion etching method utilizing a source gas selected from the group consisting of CF₄, CHF₃, C₂F₆ and C₃F₈ to form a liner layer of silicon dioxide along each sidewall of said trench, said liner layer having a width tapered from the top of said trench to the bottom thereof.

21. The method of claim 1, wherein said second conductor layer is formed of a polysilicon layer.

22. The method of claim 21, wherein the steps of forming said polysilicon layer comprises forming a polysilicon layer by way of a low pressure chemical vapor deposition method utilizing SiH₄ as the reaction gas at the temperature of about 600˜650° C. and the operation pressure of about 0.3˜0.6 torr, and then proceeding a reactive ion etching method utilizing a source gas selected from the group consisting of Cl₂, HCl and SiCl₄.
